(19) United States
(12) Patent Application Publication
(10) Pub. No.: US 2025/0096103 A1
(43) Pub. Date: Mar. 20, 2025

(54) SEMICONDUCTOR DEVICE

(71) Applicant: SAMSUNG ELECTRONICS CO., LTD., SUWON-SI (KR)

(72) Inventor: Sunjun KIM, Suwon-si (KR)

(21) Appl. No.: 18/825,412

(22) Filed: Sep. 5, 2024

(30) Foreign Application Priority Data
Sep. 18, 2023 (KR) 10-2023-0123819

(51) Int. Cl. H01L 23/498; H01L 23/00; H01L 23/31

(52) U.S. Cl. CPC H01L 23/49838; H01L 23/49822; H01L 23/3107; H01L 23/49816; H01L 24/16; H01L 2224/16227

(57) ABSTRACT

A semiconductor device includes a base substrate and a semiconductor chip disposed on the base substrate. The base substrate includes a core substrate, first interconnection substrates disposed on a first surface of the core substrate and a second surface opposite to the first surface, a first through-electrode penetrating the core substrate, a second through-electrode penetrating the core substrate and the first interconnection substrates, having a same central axis as the first through-electrode, and having a width narrower than a width of the first through-electrode, and a first insulating layer disposed between the first through-electrode and the second through-electrode and surrounding at least a portion of a side surface of the second through-electrode.

### CROSS-REFERENCE TO RELATED APPLICATION(S)

This application claims priority under 35 U.S.C. § 119 to Korean Patent Application No. 10-2023-0123819, filed on Sep. 18, 2023 in the Korean Intellectual Property Office, the disclosure of which is incorporated by reference herein in its entirety.

### TECHNICAL FIELD

Example embodiments of the present disclosure relate to a semiconductor device.

### DISCUSSION OF RELATED ART

As demands for high performance, speed, and/or multifunctionality in a semiconductor device have increased, it is desirable to increase integration density of a semiconductor device.

### SUMMARY

An example embodiment of the present disclosure is to provide a semiconductor device having increased integration density and increased reliability.

According to an example embodiment of the present disclosure, a semiconductor device includes a base substrate, and a semiconductor chip disposed on the base substrate. The base substrate includes a core substrate, a plurality of first interconnection substrates disposed on a first surface of the core substrate and a second surface of the core substrate opposite to the first surface, a first through-electrode penetrating the core substrate, a second through-electrode penetrating the core substrate and the first interconnection substrates, having a same central axis as the first through-electrode, and having a width narrower than a width of the first through-electrode, and a first insulating layer disposed between the first through-electrode and the second through-electrode and surrounding at least a portion of a side surface of the second through-electrode. The semiconductor chip is electrically connected to at least a portion of the first and second through-electrodes.

According to an example embodiment of the present disclosure, a semiconductor device includes a base substrate, and a semiconductor chip disposed on the base substrate. The base substrate includes a core substrate, a plurality of first interconnection substrates disposed on a first surface of the core substrate and a second surface of the core substrate opposite to the first surface, a first via hole penetrating the core substrate, a second via hole penetrating the core substrate and the first interconnection substrates, having a same central axis as the first via hole, and having a width narrower than a width of the first via hole, a first conductive plug disposed on an internal wall of the first via hole, and a second conductive plug disposed in at least a portion of the second via hole.

According to an example embodiment of the present disclosure, a semiconductor device includes a base substrate including a core substrate, a plurality of first interconnection substrates disposed on each of a first surface of the core substrate and a second surface of the core substrate opposite to the first surface and including a plurality of first interconnection layers, a plurality of second interconnection substrates disposed on the first interconnection substrates and including a plurality of second interconnection layers, and a plurality of first through-via structures penetrating at least a portion of the core substrate, the first interconnection substrates, and the second interconnection substrates. The semiconductor device further includes a semiconductor chip disposed on the base substrate and electrically connected to at least a portion of the first and second interconnection layers. At least a portion of the plurality of first through-via structures includes a first through-electrode penetrating the core substrate and in contact with the first interconnection layers, a second through-electrode penetrating the core substrate and the first interconnection substrate, having a same central axis as the first through-electrode, having a width narrower than a width of the first through-electrode, and in contact with the second interconnection layers, and a first insulating layer disposed between the first through-electrode and the second through-electrode and substantially on a same level as the first interconnection layers.

### BRIEF DESCRIPTION OF THE DRAWINGS

The above and other features of the present disclosure will become more apparent by describing in detail embodiments thereof with reference to the accompanying drawings, in which:

FIG. 1 is a plan diagram illustrating a semiconductor package according to an example embodiment of the present disclosure;

FIG. 2 is a plan diagram illustrating a semiconductor package according to an example embodiment of the present disclosure;

FIGS. 3A and 3B are a perspective diagram and a plan diagram, respectively, illustrating a through-via structure according to an example embodiment of the present disclosure;

FIG. 4 is an enlarged diagram illustrating a portion of a semiconductor package according to an example embodiment of the present disclosure;

FIGS. 5A and 5B are a perspective diagram and a plan diagram, respectively, illustrating a through-via structure according to an example embodiment of the present disclosure;

FIGS. 6A and 6B are a perspective diagram and a plan diagram, respectively, illustrating a through-via structure according to an example embodiment of the present disclosure;

FIG. 7 is a cross-sectional diagram illustrating a semiconductor package according to an example embodiment of the present disclosure;

FIGS. 8A and 8B are a perspective diagram and a plan diagram, respectively, illustrating a through-via structure according to an example embodiment of the present disclosure;

FIG. 9 is an enlarged diagram illustrating a portion of a semiconductor package according to an example embodiment of the present disclosure;

FIGS. 10A and 10B are a perspective diagram and a plan diagram, respectively, illustrating a through-via structure according to an example embodiment of the present disclosure;

FIGS. 11A and 11B are a perspective diagram and a plan diagram, respectively, illustrating a through-via structure according to an example embodiment of the present disclosure;

FIG. 12 is a cross-sectional diagram illustrating a semiconductor package according to an example embodiment of the present disclosure;

FIG. 13 is an enlarged diagram illustrating a portion of a semiconductor package according to an example embodiment of the present disclosure;

FIGS. 14A, 14B, 15A, 15B, 16A, 16B, 17A, 17B, 18A, 18B, 19A, and 19B are plan diagrams and cross-sectional diagrams illustrating a method of manufacturing a semiconductor package according to an example embodiment of the present disclosure; and

FIGS. 20A, 20B, 21A, 21B, 22A, 22B, 23A, 23B, 24A, 24B, 25A, and 25B are plan diagrams and cross-sectional diagrams illustrating a method of manufacturing a semiconductor package according to an example embodiment of the present disclosure.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

It will be further understood that when two components are described as being disposed on substantially a same level, the two components are disposed exactly on a same level, or are disposed approximately on a same level within a measurement error as would be understood by a person having ordinary skill in the art.

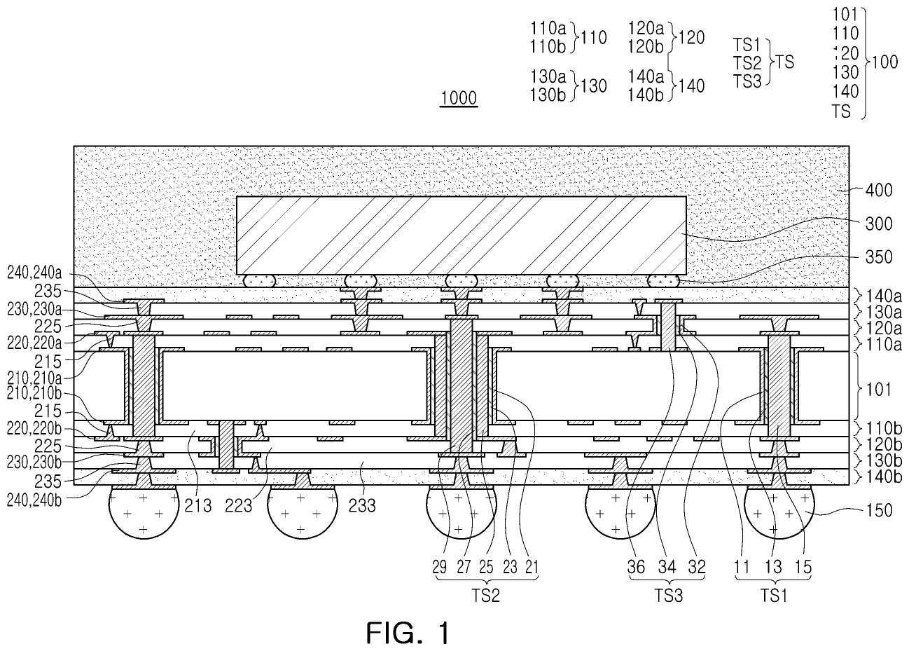

FIG. 1 is a plan diagram illustrating a semiconductor package according to an example embodiment.

Referring to FIG. 1, a semiconductor package 1000 in an example embodiment may include a base substrate 100 including at least one or more substrates 101, 110, 120, 130, and 140 and a plurality of through-via structures TS, and a semiconductor chip 300 mounted on the base substrate 100.

The base substrate 100 may be configured as a support substrate for a package substrate on which the semiconductor chip 300 is mounted, and may be a substrate (or “package substrate”) for a semiconductor package, including, for example, a printed circuit board (PCB), a ceramic substrate, a glass substrate, and a tape interconnection substrate.

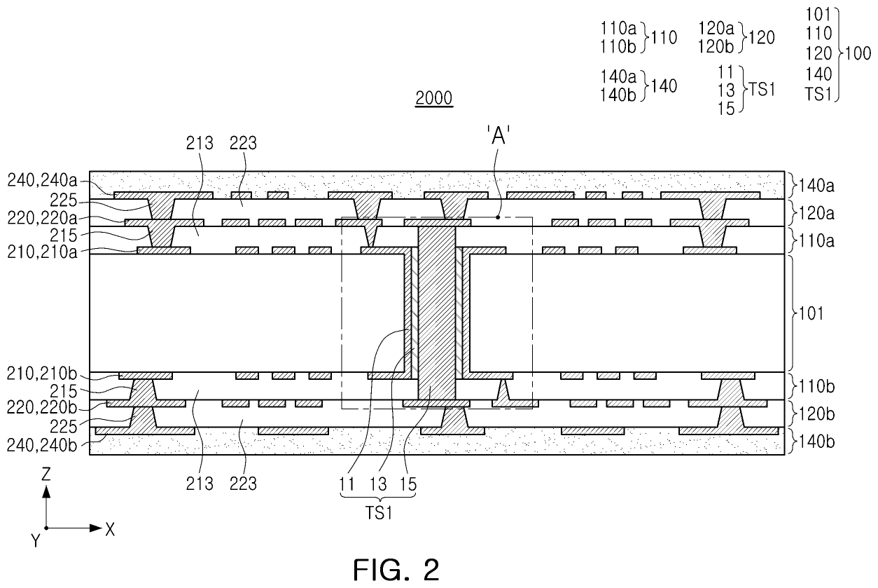

The base substrate 100 may include a plurality of substrates 101, 110, 120, 130, and 140, and a plurality of through-via structures TS. For example, the base substrate 100 may include a core substrate 101, first interconnection substrates 110, second interconnection substrates 120, and third interconnection substrates 130 disposed on upper and lower surfaces of the core substrate 101, a plurality of substrates including passivation layers 140, and a plurality of through-via structures TS including a first through-via structure TS1, a second through-via structure TS2, and a third through-via structure TS3. However, the number of interconnection substrates disposed on the core substrate 101 is not limited thereto. The base substrate 100 including the plurality of substrates 101, 110, 120, 130, and 140 and the plurality of through-via structures TS will be described in greater detail below with reference to FIGS. 2, 7, and 12.

The semiconductor chip 300 may include memory chips or memory devices which store or output data in response to address commands and control commands received from the base substrate 100. For example, the semiconductor chip 300 may include a logic chip such as, for example, a central processor (CPU), a graphics processor (GPU), a field programmable gate array (FPGA), an application processor (AP), a digital signal processor, a cryptographic processor, a microprocessor, a microcontroller, an analog-to-digital converter, and an application-specific IC (ASIC), and a memory chip (or “memory circuit”) including a volatile memory such as, for example, a dynamic RAM (DRAM), a static RAM (SRAM), and a non-volatile memory such as, for example, a phase change RAM (PRAM), a magnetic RAM (MRAM), a resistive RAM (RRAM), and a flash memory.

Connection bumps 350 may be disposed between the base substrate 100 and the semiconductor chip 300. The connection bumps 350 may be in contact with back-surface pads disposed on a back surface of the semiconductor chip 300 and front surface pads disposed on a front surface of the base substrate 100. The connection bumps 350 may include, for example, tin (Sn), indium (In), bismuth (Bi), antimony (Sb), copper (Cu), silver (Ag), zinc (Zn), lead (Pb) and/or alloys thereof. The alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, and Sn—Bi—Zn. In an embodiment, an underfill layer surrounding the connection bumps 350 disposed between the base substrate 100 and semiconductor chip 300 and fixing the semiconductor chip 300 on the base substrate 100 may be further disposed. The underfill layer may include an insulating material. The underfill layer may be formed using a capillary underfill (CUF) process, but example embodiments thereof are not limited thereto.

An encapsulant 400 surrounding the semiconductor chip 300 may be disposed on one surface of the base substrate 100. The encapsulant 400 may be formed of an insulating material such as, for example, an epoxy mold compound (EMC), but the material of the encapsulant 400 is not limited to any particular example.

External connection terminals 150 may be further disposed below the base substrate 100. The external connection terminals 150 may be in contact with pads disposed on a lower surface of base substrate 100. The external connection terminals 150 may include a material similar to the connection bumps 350 disposed between the base substrate 100 and the semiconductor chip 300. However, the materials of the connection bumps 350 and the external connection terminals 150 are not limited to the above materials.

FIG. 2 is a plan diagram illustrating a semiconductor package 2000 according to an example embodiment.

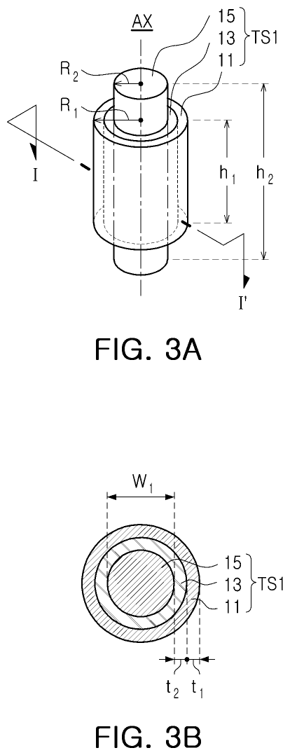

FIGS. 3A and 3B are a perspective diagram and a plan diagram, respectively, illustrating a first through-via structure TS1 of the semiconductor package 2000 according to an example embodiment. For example, FIG. 3A is a perspective diagram illustrating the first through-via structure TS1 in region “A” in FIG. 2, and FIG. 3B illustrates a cross-sectional surface taken along section line I-I′ in FIG. 3A.

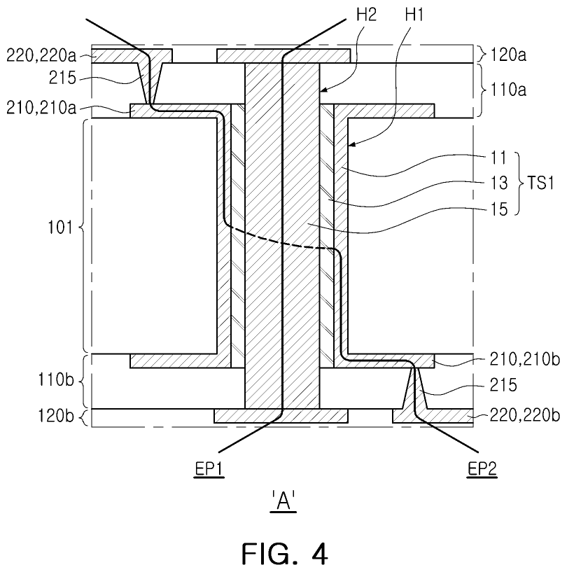

FIG. 4 is an enlarged diagram illustrating a portion of a semiconductor package according to an example embodiment, illustrating region “A.”

Referring to FIG. 2, the semiconductor package 2000 in an example embodiment may include at least one substrate 101, 110, 120, and 140, and a base substrate 100 including the first through-via structure TS1.

The base substrate 100 may be configured as a support substrate for a package substrate on which the semiconductor chip 300 is mounted, and may be configured as a substrate for a semiconductor package including, for example, a printed circuit board (PCB), a ceramic substrate, a glass substrate, and a tape interconnection substrate (see FIG. 1). The body of the package substrate may include different materials depending on the type of substrate. For example, when the package substrate is configured as a printed circuit board, an interconnection layer may be further stacked on an end surface or both surfaces of the body copper clad laminate or a copper clad laminate.

The base substrate 100 may include a core substrate 101, first interconnection substrates 110 disposed on upper and lower surfaces of the core substrate 101, and second interconnection substrates 120 disposed on the first interconnection substrates 110.

The core substrate 101 may be disposed at a center of the base substrate 100. The core substrate 101 may include an organic insulating substrate such as, for example, a glass epoxy substrate, a polyimide substrate, or bismaleimide triazine substrate, but example embodiments thereof are not limited thereto.

The first interconnection substrates 110 may include a first upper interconnection substrate 110a and a first lower interconnection substrate 110b. The first upper interconnection substrate 110a may be configured as a first upper built-up layer built up on an upper surface of the core substrate 110. The first lower interconnection substrate 110_b may be configured as the first lower built-up layer built up on a lower surface of core substrate 110.

The first upper interconnection substrate 110a may include a first interlayer insulating layer 213 and a first interconnection layer 210. The first interlayer insulating layer may include, for example, flowable oxide (FOX), tonen silazane (TOSZ), undoped silica glass (USG), borosilica glass (BSG), phosphosilaca glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD) oxide or a combination thereof. The first interlayer insulating layer may be formed using, for example, chemical vapor deposition (CVD), a flowable-CVD process, or a spin coating process.

The first interconnection layer 210 may be buried in the first interlayer insulating layer 213. The first interconnection layer 210 may be formed as a multilayer structure including an interconnection pattern and a via formed of, for example, aluminum (Al), gold (Au), cobalt (Co), copper (Cu), nickel (Ni), lead (Pb), tantalum (Ta), tellurium (Te), titanium (Ti), tungsten (W) or a combination thereof. In an example embodiment, the first interconnection layer 210 of the first upper interconnection substrate 110a may include a first lower pad 210a disposed on a lower portion (or “upper surface of the core substrate 101”) of the first upper interconnection substrate 110a.

The first lower interconnection substrate 110b may also include a first interlayer insulating layer 213 and a first interconnection layer 210. The first interlayer insulating layer 213 and the first interconnection layer 210 of the first lower interconnection substrate 110b may have characteristics the same as or similar to those of the first interlayer insulating layer 213 and the first interconnection layer 210 of the first upper interconnection substrate 110a. In an example embodiment, the first interconnection layer 210 of the first lower interconnection substrate 110b may include a first upper pad 210c disposed on an upper portion of the first lower interconnection substrate 110b (or “a lower portion of the core substrate 101”).

The second interconnection substrates 120 may include a second upper interconnection substrate 120a and a second lower interconnection substrate 120b. The second upper interconnection substrate 120a may be configured as a second upper built-up layer built up on an upper surface of the first upper interconnection substrate 110a. The second lower interconnection substrate 120b may be configured as a first lower built-up layer built up on a lower surface of the first lower interconnection substrate 110b.

The second upper interconnection substrate 120a may include a second interlayer insulating layer 223 and a second interconnection layer 220. The second interlayer insulating layer 223 of the second upper interconnection substrate 120a may have characteristics the same as or similar to those of the first interlayer insulating layer 213 of the first upper interconnection substrate 110a. The second interconnection layer 220 may include a material the same as or similar to that of the first interconnection layer 210. In an example embodiment, the second interconnection layer 220 of the second upper interconnection substrate 120a may include a second lower pad 220a disposed on a lower portion of the second upper interconnection substrate 120a (or “upper surface of the first upper interconnection substrate 110a”).

The second lower interconnection substrate 120b may also include a second interlayer insulating layer 223 and a second interconnection layer 220. The second interlayer insulating layer 223 and the second interconnection layer 220 of the second lower interconnection substrate 120b may have characteristics the same as or similar to those of the second interlayer insulating layer 223 and the second interconnection layer 220 of the second upper interconnection substrate 120a. In an example embodiment, the second interconnection layer 220 of the second lower interconnection substrate 120b may include a second upper pad 220b disposed on an upper portion of the second lower interconnection substrate 120b (or “a lower portion of the first lower interconnection substrate 110b”).

The first via plug 215 may be disposed on the first interconnection substrates 110. In the first upper interconnection substrate 110a, the first via plug 215 may electrically connect the first lower pad 210a to the second lower pad 220a. In the first lower interconnection substrate 110b, the first via plug 215 may electrically connect the first upper pad 210b to the second upper pad 220b.

Passivation layers 140 may be disposed on the second interconnection substrates 120. The passivation layers 140 may be disposed on an outermost portion of the semiconductor package 2000. The passivation layers 140 may include an upper passivation layer 140a and a lower passivation layer 140b. The upper passivation layer 140a may be disposed on an upper surface of the second upper interconnection substrate 120a. The lower passivation layer 140b may be disposed on a lower surface of the second lower interconnection substrate 120b. A material of passivation layers 140 is not limited to any particular example. For example, a material of the passivation layers 140 may be photosensitive insulating resin and photosensitive insulating material, or solder resist may also be used. When solder resist is used as a material of the passivation layers 140, the passivation layers 140 may be referred to as solder resist layers.

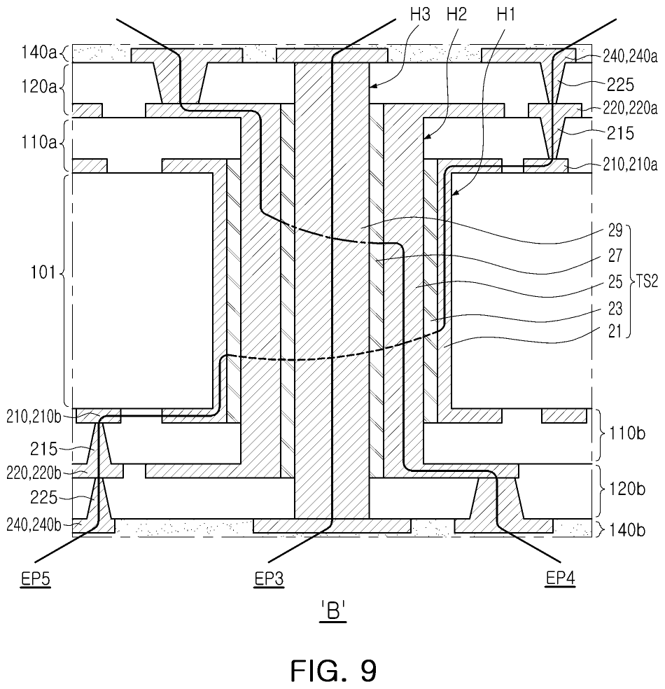

The passivation layer 140 may include an upper interconnection layer 240. The upper interconnection layer 240 may be included in the passivation layer 140 disposed on an outermost portion of the semiconductor package 2000. The upper interconnection layer 240 may include a material the same as or similar to that of the first and second interconnection layers 210 and 220. The upper interconnection layer 240 of the upper passivation layer 140a may include a lower-surface pad 240a disposed on a lower portion of the upper passivation layer 140a (or “upper surface of the second upper interconnection substrate 120a”). In an example embodiment, the upper passivation layer 140a may further include a front surface pad disposed on a front surface, and a via plug electrically connecting the lower-surface pad 240a to the front surface pad (see FIG. 9).

The lower passivation layer 140b may also include an interconnection layer corresponding to the upper interconnection layer 240. The interconnection layer of the lower passivation layer 140b may have characteristics the same as or similar to those of the upper interconnection layer 240 of the upper passivation layer 140a. The interconnection layer of the lower passivation layer 140b may include an upper surface pad 240b disposed on an upper surface of the lower passivation layer 140b (or “a lower portion of the second lower interconnection substrate 120b”). In an example embodiment, the lower passivation layer 140b may further include a back-surface pad disposed on a back surface, and a via plug electrically connecting the upper surface pad 240b and the back-surface pad (see FIG. 9).

The second via plug 225 may be disposed on the second interconnection substrates 120. In the second upper interconnection substrate 120a, the second via plug 225 may electrically connect the second lower pad 220a to the lower-surface pad 240a. In the second lower interconnection substrate 120b, the second via plug 225 may electrically connect the second upper pad 220b to the upper surface pad 240b.

The first through-via structure TS1 may include first and second through-electrodes 11 and 15, and a first insulating layer 13.

The first through-electrode 11 may penetrate through at least a portion of the base substrate 100. For example, the first through-electrode 11 may extend vertically to penetrate through the core substrate 101 in the first via hole H1. The first through-electrode 11 may include a conductive material. The first through-electrode 11 may include, for example, aluminum (Al), gold (Au), cobalt (Co), copper (Cu), nickel (Ni), lead (Pb), tantalum (Ta), tellurium (Te), titanium (Ti), tungsten (W) or a combination thereof. Electroless plating or electrolytic plating may be used to form the first through-electrode 11.

The second through-electrode 15 may penetrate through at least a portion of the base substrate 100. For example, the second through-electrode 15 may extend vertically to penetrate through the core substrate 101 and the first interconnection substrates 110 in the second via hole H2. Here, the first via hole H1 and the second via hole H2 may have the same central axis AX, and the first via hole H1 may surround at least a portion of the circumference of the second via hole H2. Accordingly, the first through-electrode 11 and the second through-electrode 15 may have the same central axis AX, and the first through-electrode 11 may surround at least a portion of a circumference of the second through-electrode 15. Referring to FIG. 2, an external side surface of the first through-electrode 12 may be disposed further from the central axis AX than an external side surface of the second through-electrode 15. The second through-electrode 15 may have a material the same as or similar to that of the first through-electrode 11, but example embodiments thereof are not limited thereto. To form the second through-electrode 15, electroless plating or electrolytic plating may be used.

An upper surface of the second through-electrode 15 may be on a level higher than a level of an upper surface of the first through-electrode 11. For example, the upper surface of the first through-electrode 11 may be on substantially the same level as a level of the upper surface of the core substrate 101. The upper surface of the second through-electrode 15 may be on substantially the same level as a level of an upper surface of the first upper interconnection substrate 110a. Referring to FIGS. 3A, 3B and 4 together, the upper surface of the first through-electrode 11 may be in contact with the first interconnection layers 210 and 210a, and the upper surface of the second through-electrode 15 may be in contact with the second interconnection layers 220 and 220a.

The first insulating layer 13 may be disposed between the first through-electrode 11 and the second through-electrode 15. The first insulating layer 13 may isolate the first through-electrode 11 and the second through-electrode 15 from each other. The first insulating layer 13 may extend vertically to penetrate through the core substrate 101 between the first through-electrode 11 and the second through-electrode 15 in a first via hole H1. At least a portion of the first insulating layer 13 may extend into the first interlayer insulating layer 213 of the first interconnection substrate 110. An upper surface of the first insulating layer 13 may be on substantially the same level as a level of an upper surface of the first interconnection layers 210 and 210a. For example, the first insulating layer 13 may be formed of, for example, Ajinomoto built-up film (ABF), prepreg (PPG), or a combination thereof. A hole plugging land (HPL) process may be used to form the first insulating layer 13.

Referring to FIGS. 3A, 3B and 4 together, the first and second through-electrodes 11 and 15, and the first insulating layer 13 included in the first through-via structure TS1 may have a predetermined three-dimensional shape. The three-dimensional shape may extend vertically with a uniform width.

Referring to FIG. 3A, the second through-electrode 15 may have a cylindrical shape. An external side surface of the second through-electrode 15 may be spaced apart from a central axis AX by a second distance R₂. The first through-electrode 11 may have a cylindrical shape which surrounds at least a portion of a side surface of the second through-electrode 15 and is hollow therein. An external side surface of the first through-electrode 11 may be spaced apart from the central axis AX by a first distance R₁. The first distance R₁ may be greater than the second distance R₂. The first distance R₁ may be about 200 μm or less, for example, about 30 μm to about 200 μm, about 40 μm to about 180 μm, about 50 μm to about 150 μm, or about 75 μm to about 135 μm. The second distance R₂ may be about 50 μm or less, for example, about 15 μm to about 50 μm, about 20 μm to about 40 μm, or about 25 μm to about 35 μm. The first insulating layer 13 may be disposed closer to the central axis AX than the first through-electrode 11 and may have a cylindrical shape which surrounds at least a portion of a side surface of the second through-electrode 15 and is hollow therein. The external side surface of the first insulating layer 13 may be spaced apart from the central axis AX by a distance between the first distance R₁ and the second distance R₂.

Referring again to FIG. 3A, the first through-via structure TS1 may have a structure having a step difference in a direction away from the central axis AX. In other words, a length of the second through-electrode 15 (or “second height h2”) in the vertical direction may be longer than a length of the first insulating layer 13 and the first through-electrode 11 (or “first height h₁”) in the vertical direction. The second height h2 may be about 2500 μm or less, for example, about 60 μm to about 2500 μm, about 100 μm to about 2000 μm, about 150 μm to about 1800 μm, about 200 μm to about 1600 μm, about 250 μm to about 1500 μm, about 300 μm to about 1400 μm, about 350 μm to about 1300 μm, about 400 μm to about 1200 μm, about 450 μm to about 1100 μm, or about 500 μm to about 1000 μm. The first height h₁ may be about 2000 μm or less, for example, about 20 μm to about 2000 μm, about 50 μm to about 1800 μm, about 100 μm to about 1600 μm, about 150 μm to about 1500 μm, about 200 μm to about 1400 μm, about 250 μm to about 1300 μm, about 300 μm to about 1200 μm, about 350 μm to about 1100 μm, about 400 μm to about 1000 μm, about 450 μm to about 900 μm, or about 500 μm to about 800 μm.

Referring to FIG. 3B, the cross-sectional surface of the first through-via structure TS1 along line I-I′ may have a circular shape. The second through-electrode 15 may have a circular cross-sectional surface having a first width W₁ (or “first diameter”) formed in a horizontal direction. The first insulating layer 13 may have a circular cross-sectional surface which is hollow therein and has a second thickness t2. The first through-electrode 11 may have a circular cross-sectional surface which is hollow therein and has a first thickness t₁. A first width W₁ may be about 100 μm or less, for example, about 30 μm to about 100 μm, about 40 μm to about 80 μm, or about 50 μm to about 70 μm. The second thickness t2 may be about 50 μm or less, for example, about 5 μm to about 50 μm, about 10 μm to about 40 μm, or about 20 μm to about 30 μm. The first thickness t₁ may be about 100 μm or less, for example, about 10 μm to about 100 μm, about 20 μm to about 80 μm, about 30 μm to about 70 μm, or about 40 μm to about 60 μm.

Referring to FIG. 4, the second through-electrode 15 may electrically connect the second interconnection layer 220 (or “second lower pad 220a”) disposed on the second upper interconnection substrate 120a to the second interconnection layer 220 (or “second upper pad 220b”) disposed on the second lower interconnection substrate 120b. Accordingly, at least a portion of the plurality of second interconnection layers 220 disposed on the second interconnection substrates 120 may form the first electrical signal path EP1 through the second through-electrode 15.

The first through-electrode 11 may electrically connect the first interconnection layer 210 (or “first lower pad 210a”) disposed on the first upper interconnection substrate 110a to the first interconnection layer 210 (or “second upper pad 210b”) disposed on the first lower interconnection substrate 110b. The first via plug 215 may electrically connect the first interconnection layer 210 to the second interconnection layer 220. Accordingly, at least a portion of the plurality of second interconnection layers 220 disposed on the second interconnection substrates 120 may be electrically connected to the first through-electrode 11 through the first via plug 215, and accordingly, a second electrical signal path EP2 may be formed.

As the electrically insulated plurality of through-electrodes 11 and 13 form a single through-via structure TS1, the interconnection layers 210 and 220 disposed on the interconnection substrates 110 and 120, respectively, may transmit and receive signals through a shorter electrical connection path. In an example embodiment, as the electrical signal path is shortened, when the base substrate 100 is used as a support substrate for a package substrate on which the semiconductor chip 300 is mounted (see FIG. 9), the effect of reducing a size of the package may be obtained.

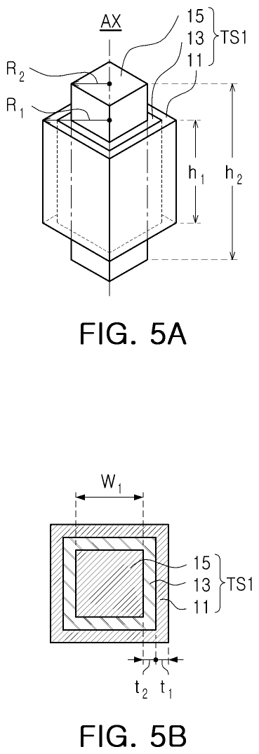

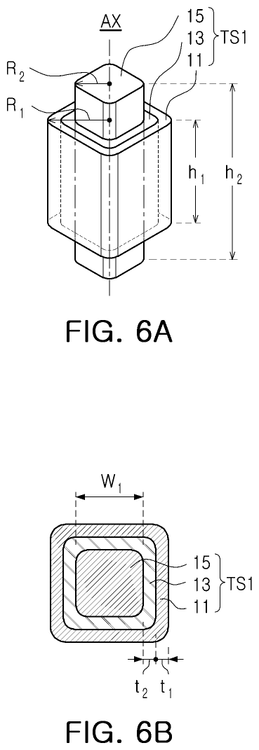

FIGS. 5A, 5B, 6A and 6B are perspective diagrams and plan diagrams illustrating a through-via structure according to an example embodiment. For example, FIGS. 5A and 6A are perspective diagrams illustrating a first through-via structure TS1 in region “A” in FIG. 2, and FIG. 5B and FIG. 6B illustrate cross-sectional surfaces taken along lines II-II′ in FIG. 5A and FIG. 6A, respectively.

Referring to FIGS. 5A and 5B, an example embodiment may be configured the same as or similar to the example described with reference to FIGS. 3A and 3B, other than the configuration in which the cross-sectional surfaces of the first and second through-electrodes 11 and 15, and the first insulating layer 13 taken along line I-I′, included in the first through-via structure TS1, may have the shape of a quadrangular pillar having a square shape.

Referring to FIGS. 6A and 6B, an example embodiment may be configured the same as or similar to an example described with reference to FIGS. 3A and 3B, other than the configuration in which the cross-sectional surface of the first and second through-electrode 11 and 15, and the first insulating layer 13 taken along line I-I′, included in the first through-via structure TS1, may have a rounded square pillar having vertices having a rounded square shape.

Referring to FIGS. 5A and 6A, a size of a distance furthest from the central axis AX among the external side surfaces of the second through-electrode 15 may be substantially the same as the second distance R₂ described with reference to FIG. 3A. Similarly, a size of the distance furthest from the central axis AX among the external side surfaces of first through-electrode 11 may be substantially the same as each of the second distances R₂ described with reference to FIG. 3A. The length of the second through-electrode 15 in the vertical direction may be substantially the same as the second height h₂ described with reference to FIG. 3A. Similarly, the lengths of the first insulating layer 13 and the first through-electrode 11 in the vertical direction may be substantially the same as the first height h₁ described with reference to FIG. 3A.

Referring to FIGS. 5B and 6B together, a width formed in the horizontal direction of the second through-electrode 15 may be substantially the same as the first width W₁ described with reference to FIG. 3B. Similarly, thicknesses of the first through-electrode 11 and the first insulating layer 13 may be substantially the same as the first thickness t₁ and the second thickness t₂, respectively, described with reference to FIG. 3B.

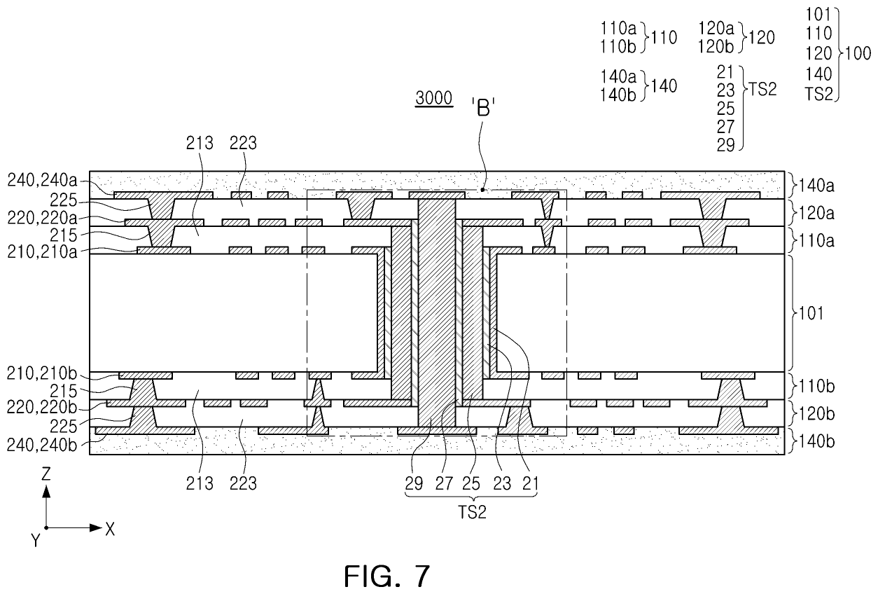

FIG. 7 is a cross-sectional diagram illustrating a semiconductor package 3000 according to an example embodiment.

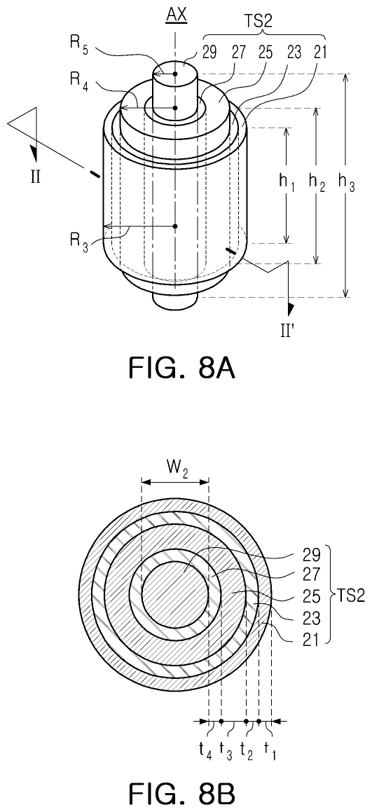

FIGS. 8A and 8B are a perspective diagram and a plan diagram, respectively, illustrating a second through-via structure TS2 of a semiconductor package 3000 according to an example embodiment. For example, FIG. 8A is a perspective diagram illustrating the second through-via structure TS2 in region “B” in FIG. 7, and FIG. 8B illustrates a cross-sectional surface taken along line II-II′ in FIG. 8A.

FIG. 9 is an enlarged diagram illustrating a portion of a semiconductor package 3000 according to an example embodiment, illustrating region “A.”

Referring to FIG. 7, the semiconductor package 3000 may be configured the same as or similar to an example embodiment described with reference to FIGS. 2 to 4, other than the configuration in which the base substrate 100 includes a second through-via structure TS2 including three or more through-electrodes 21, 25, and 29.

Referring to FIG. 7, the second through-via structure TS2 may include first, second, and third through-electrodes 21, 25, and 29, and first and second insulating layers 23 and 27.

In this example embodiment, the first through-electrode 21 may be referred to as a first through-via electrode, the second through-electrode 25 may be referred to as a second through-via electrode, and the third through-electrode 29 may be referred to as a third through-via electrode. The first insulating layer 23 may be referred to as a first gap-fill insulating layer, and the second insulating layer 27 may be referred to as a second gap-fill insulating layer.

The first through-electrode 21, the first insulating layer 23, and the second through-electrode 25 included in the second through-via structure TS2 may be configured the same as or similar to the first through-electrode 11, the first insulating layer 13, and the second through-electrode 15 of the first through-via structure TS1 described with reference to FIGS. 2 to 4. Therefore, for convenience of explanation, a further description thereof will be omitted.

The third through-electrode 29 may penetrate through at least a portion of the base substrate 100. For example, the third through-electrode 29 may extend vertically to penetrate through the core substrate 101, the first interconnection substrates 110, and the second interconnection substrates 120 in the third via hole H3. Here, the first via hole H1, the second via hole H2, and the third via hole H3 may have the same central axis AX, and the second via hole H2 may surround at least a portion of a circumference of the third via hole H3. Accordingly, the first through-electrode 21, the second through-electrode 25, and the third through-electrode 29 may have the same central axis AX, and the second through-electrode 25 may surround at least a portion of the third through-electrode 29. Referring to FIG. 8, an external side surface of the second through-electrode 25 may be spaced apart from the central axis AX more than an external side surface of the third through-electrode 21. The third through-electrode 25 may have a material the same as or similar to that of the first through-electrode 21 and the second through-electrode 25, but example embodiments thereof are not limited thereto.

An upper surface of the third through-electrode 29 may be disposed on a level higher than a level of an upper surface of the second through-electrode 25. For example, an upper surface of the second through-electrode 25 may be disposed on substantially the same level as a level of an upper surface of the first upper interconnection substrate 110a. An upper surface of the third through-electrode 29 may be on substantially the same level as a level of an upper surface of the second upper interconnection substrate 120a. Referring to FIGS. 6 and 7 together, an upper surface of the second through-electrode 15 may be in contact with the second interconnection layers 220 and 220a, and an upper surface of the third through-electrode 17 may be in contact with the third interconnection layers 230 and 230a.

The second insulating layer 27 may be disposed between the second through-electrode 25 and the third through-electrode 29. The second insulating layer 27 may isolate the second through-electrode 25 and the third through-electrode 29 from each other. The second insulating layer 27 may extend vertically to penetrate through the core substrate 101 and the first interconnection substrates 110 between the second through-electrode 25 and the third through-electrode 29 in the third via hole H3. At least a portion of the second insulating layer 27 may extend into the second interlayer insulating layer 223 of the second interconnection substrate 120. An upper surface of the second insulating layer 27 may be on substantially the same level as a level of an upper surface of the second interconnection layers 220 and 220a. The second insulating layer 27 may include a material the same as or similar to that of the first insulating layer 13 described with reference to FIGS. 2 to 6, but example embodiments thereof are not limited thereto.

Referring to FIGS. 8A and 8B, the first, second, and third through-electrodes 21, 25, and 29, and first and second insulating layers 23 and 27 included in the second through-via structure TS2 may have a predetermined three-dimensional shape. The three-dimensional shape may be a three-dimensional shape extending vertically with a uniform width.

Referring to FIG. 8A, the third through-electrode 29 may have a cylindrical shape. An external side surface of the third through-electrode 29 may be spaced apart from the central axis AX by a fifth distance R₅. The second through-electrode 25 may have a cylindrical shape which surrounds at least a portion of a side surface of the third through-electrode 29 and is hollow therein. An external side surface of the second through-electrode 25 may be spaced apart from the central axis AX by a fourth distance R₄. The fourth distance R₄ may be greater than the fifth distance R₅. The second insulating layer 27 may be disposed closer to the central axis AX than the second through-electrode 25 and may have a cylindrical shape which surrounds at least a portion of a side surface of the third through-electrode 29 and is hollow therein. An external side surface of the second insulating layer 27 may be spaced apart from the central axis AX by a distance between the fifth distance R₅ and the fourth distance R₄. The first through-electrode 21 may have a cylindrical shape which surrounds at least a portion of a side surface of the second through-electrode 25 and is hollow therein. An external side surface of the first through-electrode 21 may be spaced apart from the central axis AX by a third distance R₃. The third distance R₃ may be greater than the fourth distance R₄. The first insulating layer 23 may be disposed closer to the central axis AX than the first through-electrode 21 and may have a cylindrical shape which surrounds at least a portion of a side surface of the second through-electrode 25 and is hollow therein. An external side surface of the first insulating layer 23 may be spaced apart from the central axis AX by a distance between the fourth distance R₄ and the third distance R₃.

The third distance R₃ may be about 350 μm or less, for example, about 45 μm to about 350 μm, about 55 μm to about 330 μm, about 65 μm to about 300 μm, or about 90 μm to about 285 μm. The fourth distance R₄ may be about 200 μm or less, for example, about 30 μm to about 200 μm, about 40 μm to about 180 μm, about 50 μm to about 150 μm, or about 75 μm to about 135 μm. The fifth distance R₅ may be about 50 μm or less, for example, about 15 μm to about 50 μm, about 20 μm to about 40 μm, or about 25 μm to about 35 μm.

Referring again to FIG. 8A, the second through-via structure TS2 may have a structure with a step difference in a direction away from the central axis AX. In other words, a length (or “third height h₃”) of the third through-electrode 29 in the vertical direction may be longer than a length (or “second height h₂”) of the second through-electrode 25 in the vertical direction. Also, a length (or “second height h₂”) of the second through-electrode 25 in the vertical direction may be longer than a length (or “first height h₁”) of the first through-electrode 21 in the vertical direction.

The second height h₂ of the second through-electrode 25, and the first height h₁ of the first through-electrode 21 may be substantially the same as the second height h₂ of the second through-electrode 15, and the first height h₁ of the first through-electrode 11 described with reference to FIG. 2A. The third height h₃ may be about 3000 μm or less, for example, about 100 μm to about 3000 μm, about 150 μm to about 2500 μm, about 200 μm to about 2300 μm, about 250 μm to about 2100 μm, about 300 μm to about 2000 μm, about 350 μm to about 1900 μm, about 400 μm to about 1800 μm, about 450 μm to about 1700 μm, about 500 μm to about 1600 μm, or about 550 μm to about 1500 μm.

Referring to FIG. 8B, a cross-sectional surface of the second through-via structure TS2 taken along line II-II′ may have a circular shape. The third through-electrode 29 may have a circular cross-sectional surface having a second width W₂ (or “second diameter”) formed in the horizontal direction. The second insulating layer 27 may have a circular cross-sectional surface which is hollow therein and has a fourth thickness t₄. The second through-electrode 25 may have a circular cross-sectional surface which is hollow therein and has a third thickness t₃. The first insulating layer 23 may have a circular cross-sectional surface which is hollow therein and has a second thickness t₂. The first through-electrode 21 may have a circular cross-sectional surface which is hollow therein and has a first thickness t₁. The second width W₂ may be about 100 μm or less, for example, about 30 μm to about 100 μm, about 40 μm to about 80 μm, or about 50 μm to about 70 μm. Each of the second thickness t₂ and the fourth thickness t₄ may be about 50 μm or less, for example, about 5 μm to about 50 μm, about 10 μm to about 40 μm, or about 20 μm to about 30 μm. Each of the first thickness t₁ and the third thickness t₃ may be about 100 μm or less, for example, about 10 μm to about 100 μm, about 20 μm to about 80 μm, about 30 μm to about 70 μm, or about 40 μm to about 60 μm.

Referring to FIG. 9, the third through-electrode 29 may electrically connect the upper interconnection layer 240 (or “third lower pad 230a”) disposed on the upper passivation layer 140a to the upper interconnection layer 240 (or “third upper pad 230b”) disposed on the lower passivation layer 140b. Accordingly, at least a portion of the plurality of third interconnection layers 230 disposed in the passivation layers 140 may form a third electrical signal path EP3 through the third through-electrode 29.

The second through-electrode 25 may electrically connect the second interconnection layer 220 (or “second lower pad 220a”) disposed on the second upper interconnection substrate 120a to the second interconnection layer 220 (or “second upper pad 220b”) disposed on the second lower interconnection substrate 120b. The second via plug 225 may electrically connect the second interconnection layer 220 to the upper interconnection layer 240. Accordingly, at least a portion of the plurality of third interconnection layers 230 disposed on the passivation layers 140 may be electrically connected to the second through-electrode 25 through the second via plug 225, such that a fourth electrical signal path EP4 may be formed.

The first through-electrode 21 may electrically connect the first interconnection layer 210 (or “first lower pad 210a”) disposed on the first upper interconnection substrate 110a to the first interconnection layer 210 (or “second upper pad 210b”) disposed on the first lower interconnection substrate 110b. The first via plug 215 may electrically connect the first interconnection layer 210 to the second interconnection layer 220. Accordingly, at least a portion of the plurality of third interconnection layers 230 disposed on the passivation layers 140 may be electrically connected to the first through-electrode 21 through the first via plug 215 and the second via plug 225, such that a fifth electrical signal path EP5 may be formed.

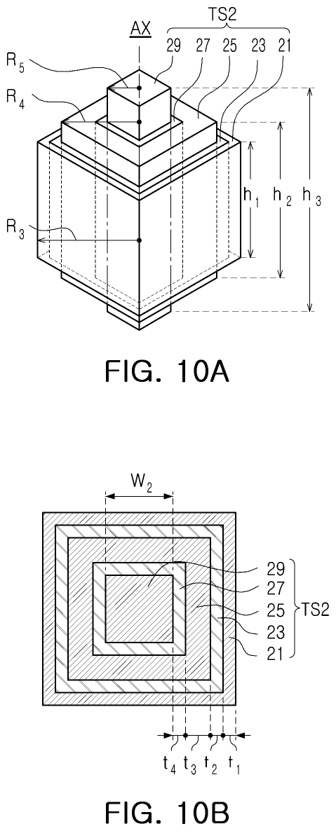

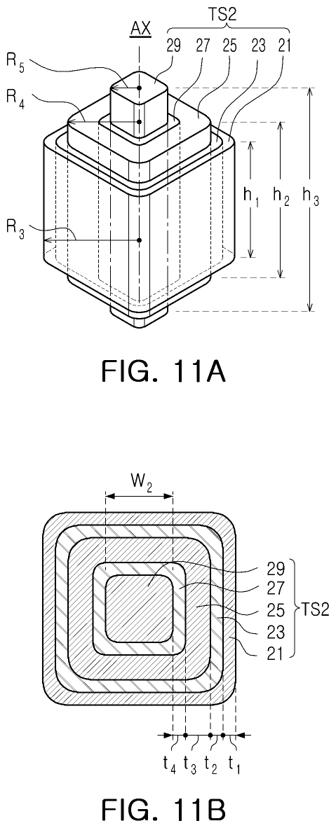

FIGS. 10A, 10B, 11A, and 11B are perspective diagrams and plan diagrams illustrating a second through-via structure TS2 of a semiconductor package 3000 according to an example embodiment. FIGS. 10A and 11A are perspective diagrams illustrating the second through-via structure TS2 in region “B” in FIG. 7, and FIGS. 10B and 11B illustrate cross-sectional surfaces taken along line II-II′ in FIGS. 10A and 10A, respectively.

Referring to FIGS. 10A and 10B, an example embodiment may be configured the same as or similar to an example embodiment in FIGS. 8A and 8B other than the configuration in which the cross-sectional surface of the first, second, and third through-electrodes 21, 25, and 29, and the first, and second insulating layers 23 and 27 taken along line II-II′, included in the second through-via structure TS2, may have a quadrangular pillar shape having a square shape.

Referring to FIGS. 11A and 11B, an example embodiment may be configured the same as or similar to an example embodiment in FIGS. 8A and 8B other than the configuration in which a vertex of the cross-sectional surface of the first, second, and third through-electrodes 21, 25, and 29, and the first, and second insulating layers 23 and 27 taken along line II-II′, included in the second through-via structure TS2, may have a rounded square pillar shape having a rounded square shape.

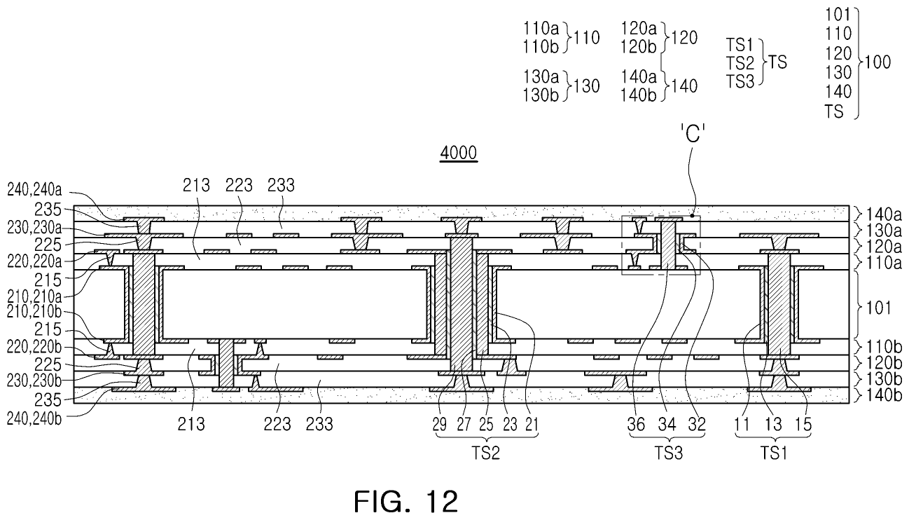

FIG. 12 is a cross-sectional diagram illustrating a semiconductor package 4000 according to an example embodiment.

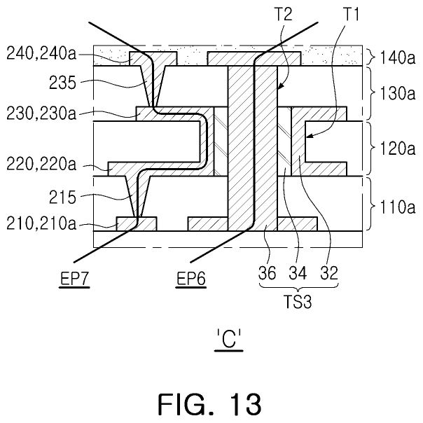

FIG. 13 is an enlarged diagram illustrating a portion of a semiconductor package according to an example embodiment, illustrating region “C.”

Referring to FIG. 12, the semiconductor package 4000 in an example embodiment may be configured the same as or similar to an example embodiment described with reference to FIGS. 2 to 11, other than the configuration in which third interconnection substrates 130 in which a base substrate 100 may be further disposed between the second interconnection substrates 120 and the passivation layers 140 may be further included, and a plurality of through-via structures TS including first, second, and third through-via structures TS1, TS2, and TS3 may be included.

In this embodiment, in order to clearly distinguish the first and second through via structures TS1 and TS2 from each other, each of the first, second, and third through-electrodes 21, 25, and 29, and each of the first and second insulating layers 23 and 27 of the second through-via structure TS2 may be referred to by different terms. For example, the first through-electrode 21 may be referred to as a first through-via electrode, the second through-electrode 25 may be referred to as a second through-via electrode, the third through-electrode 29 may be referred to as a third through-via electrode, the first insulating layer 23 may be referred to as a first gap-fill insulating layer, and the second insulating layer 27 may be referred to as a second gap-fill insulating layer.

Referring to FIG. 12, the third interconnection substrates 130 may include a third upper interconnection substrate 130a and a third lower interconnection substrate 130b. The third upper interconnection substrate 130a may be configured as a third upper built-up layer further built up on an upper surface of the second upper interconnection substrate 120a. The third lower interconnection substrate 130b may be configured as a third lower built-up layer further built up on a lower surface of the second lower interconnection substrate 120b.

The third upper interconnection substrate 130a may include a third interlayer insulating layer 233 and a third interconnection layer 230. The third interlayer insulating layer 233 of the third upper interconnection substrate 130a may have characteristics the same as or similar to those of the first interlayer insulating layer 213 of the first upper interconnection substrate 110a described with reference to FIGS. 1 to 3. The third interconnection layer 230 may include a material the same as or similar to that of the first interconnection layer 210 described with reference to FIGS. 1 to 3. In an example embodiment, the second interconnection layer 230 of the third upper interconnection substrate 130a may include a third lower pad 230a disposed on a lower portion of the third upper interconnection substrate 130a (or “upper surface of the second upper interconnection substrate 120a”).

The third lower interconnection substrate 130b may also include a third interlayer insulating layer 233 and a third interconnection layer 230. The third interlayer insulating layer 233 and the third interconnection layer 230 of the third lower interconnection substrate 130b may have characteristics the same as or similar to those of the third interlayer insulating layer 233 and the second interconnection layer 230 of the third upper interconnection substrate 130a. In an example embodiment, the third interconnection layer 220 of the third lower interconnection substrate 130b may include a third upper pad 320b disposed on an upper portion of the third lower interconnection substrate 130b (or “a lower portion of the second lower interconnection substrate 120b”).

A third via plug 235 may be disposed on the third interconnection substrates 130. In the third upper interconnection substrate 130a, the third via plug 235 may electrically connect the third lower pad 230a to the lower-surface pad 240a. In the third lower interconnection substrate 130b, the third via plug 235 may electrically connect the third upper pad 230b to the upper surface pad 240b.

Referring to FIG. 12, the base substrate 100 may include both the first through-via structure TS1 described with reference to FIGS. 2 to 6, and the second through-via structure TS2 described with reference to FIGS. 7 to 11. The base substrate 100 may further include a third through-via structure TS3 spaced apart from the first through-via structure TS1 and the second through-via structure TS2 by a predetermined distance in the horizontal and vertical directions. Here, the third through-via structure TS3 may have characteristics the same as or similar to those of the first through-via structure TS described with reference to FIGS. 2 to 6, other than the configuration in which the third through-via structure TS3 does not penetrate through the core substrate 101.

Referring to FIGS. 12 and 13 together, the third through-via structure TS3 may include first and second through-plugs 32 and 36, and a first insulating layer 34.

Similar to the above-mentioned, in this embodiment, in order to clearly distinguish the third through-via structure TS3 from the first and second through-via structures TS1 and TS2, the first insulating layer 34 of the third through-via structure TS3 may be referred to by different terms. For example, the first insulating layer 34 may be referred to as a first insulating liner.

The first through-plug 32 may extend vertically to penetrate through the first upper interconnection substrate 110a in the first through-hole T1. The second through-plug 36 may extend vertically to penetrate through the first upper interconnection substrate 110a, the second upper interconnection substrate 120a, and the third upper interconnection substrate 129a in the second through-hole T2. The first through-hole T1 and the second through-hole T2 may have the same central axis, and the first through-hole T1 may surround at least a portion of a circumference of the second through-hole T2. Accordingly, the first through-plug 32 and the second through-plug 36 may have the same central axis AX, and the first through-plug 32 may surround at least a portion of the circumference of second through-plug 36. The first through-plug 32 and the second through-plug 36 may include a material the same as or similar to that of the first and second through-electrodes 11 and 15 described with reference to FIGS. 2 to 6, but example embodiments thereof are not limited thereto.

A first insulating layer 34 may be disposed between the first through-plug 32 and the second through-plug 36. The first insulating layer 34 may isolate the first through-plug 32 and the second through-plug 36 from each other. The first insulating layer 34 may include a material the same as or similar to that of the first insulating layer 13 described with reference to FIGS. 2 to 6, but example embodiments thereof are not limited thereto.

Referring to FIG. 13, the second through-plug 36 may electrically connect the upper interconnection layer 240 (or “lower-surface pad 240a”) disposed on the third upper interconnection substrate 130a and the first interconnection layer 210 (or “first lower pad 210a”) disposed on the first upper interconnection substrate 110a. Accordingly, at least a portion of the upper interconnection layers 240 may form a sixth electrical signal path EP6 through the second through-plug 36.

The first through-plug 32 may electrically connect the third interconnection layer 230 (or “third lower pad 230a”) disposed on the second upper interconnection substrate 120a and the second interconnection layer 220 (or “second lower pad 220a”) disposed on the first upper interconnection substrate 110a. The third via plug 235 may electrically connect the third interconnection layer 230 to the upper interconnection layer 240. Accordingly, at least a portion of the upper interconnection layers 240 may be electrically connected to the first through-plug 32 through the third via plug 235, such that a seventh electrical signal path EP7 may be formed.

As the base substrate 100 for the package substrate may include a plurality of through-via structures TS including the first, second, and third through-via structures TS1, TS2, and TS3 described above, interconnection layers 210, 220, 230, and 240 in the plurality of substrates 110, 120, 130, and 140 may exchange signals more efficiently through the through-via structures TS. Accordingly, the effect of reducing the size of the package substrate may also be obtained.

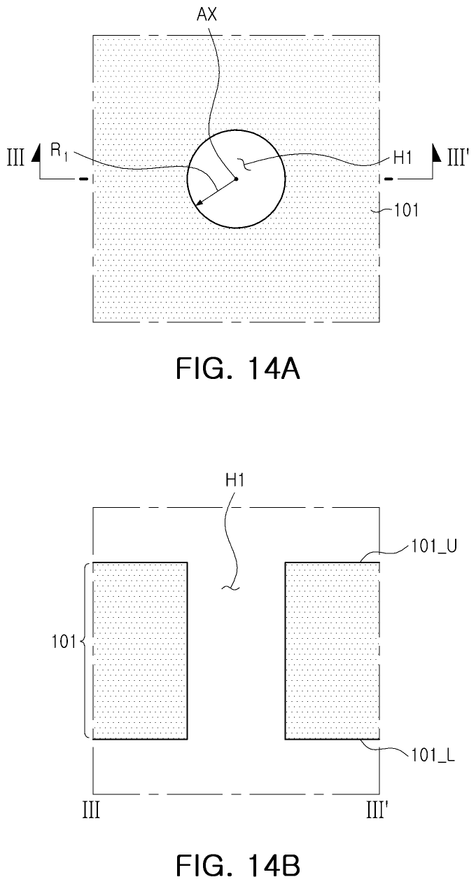

FIGS. 14A, 14B, 15A, 15B, 16A, 16B, 17A, 17B, 18A, 18B, 19A, and 19B are plan diagrams and cross-sectional diagrams illustrating a method of manufacturing a semiconductor package 2000 according to an example embodiment. FIGS. 14A to 19A are plan diagrams illustrating a method of manufacturing the semiconductor package 2000, and FIGS. 14B to 19B illustrate cross-sectional diagrams taken along lines III-III′ in FIGS. 14A to 19A, respectively.

Referring to FIGS. 14A and 14B, a process of forming a first via hole H1 penetrating through a core substrate 101 may be performed. The first via hole H1 may be formed using a mechanical drilling method or a laser processing method.

Referring to FIG. 14B, the first via hole H1 may be formed to penetrate through a first surface 101_U of the core substrate 101 and a second surface 101_L opposite to the first surface.

Referring to FIG. 14A, a distance of the first via hole H1 from a point on a central axis AX may be a first distance R₁ uniformly. In an example embodiment, the first via hole H1 may be formed to have a horizontal cross-sectional surface having a circular shape.

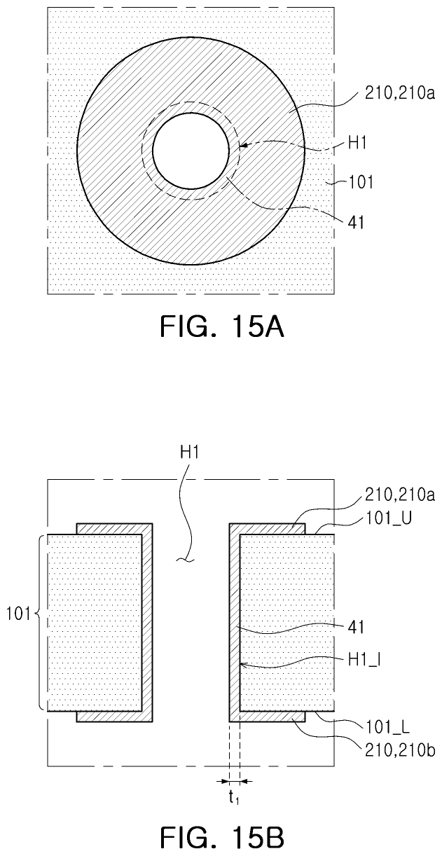

Referring to FIGS. 15A and 15B, a process of forming the first conductive film 41 may be performed on the first surface 101_U and the second surface 101_L of the core substrate 101 and a surface of the internal wall H1_I of the first via hole H1. The first conductive film 41 may be formed by electroless plating or electrolytic plating.

Referring to FIG. 15B, the first conductive film 41 may be formed to have a uniform thickness about equal to the first thickness t₁ on the internal wall H1_I of the first via hole H1. In an example embodiment, in the first via hole H1, the first conductive film 41 may be configured as a first conductive plug which is hollow therein.

Thereafter, a process of patterning a portion of the first conductive film 41 formed on the first surface 101_U and the second surface 101_L of the core substrate 101 may be performed. The patterning may be performed using a photolithography process or an etching process. By way of the patterning, a portion of the first surface 101_U and the second surface 101_L of the core substrate 101 may be exposed, and a first interconnection layer 210 including a first lower pad 210a and a first upper pad 210b may be formed on the core substrate 101.

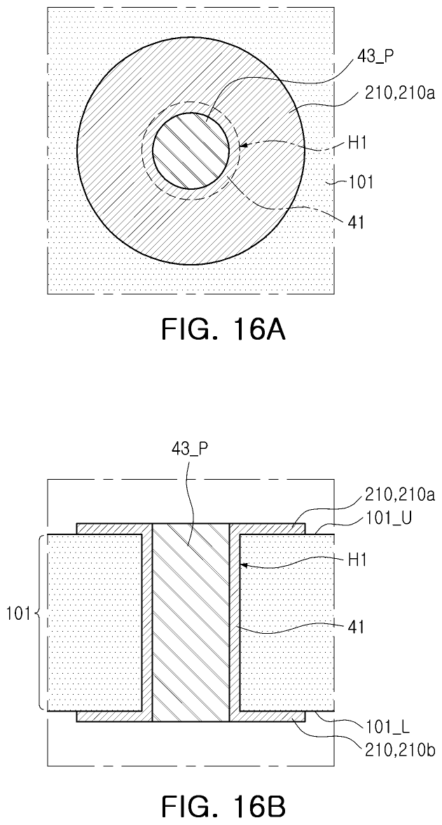

Referring to FIGS. 16A and 16B, by plugging the first via insulating material 43_p into the first via hole H1, the first via hole H1 may be completely filled with the first via insulating material 43_p. The first via insulating material 43_p may be obtained by a hole plugging land (HPL) method. By way of the above method, an end of the first via insulating material 43_p may be formed to be on substantially the same level as the first interconnection layer 210 (or “first lower pad 210a” to “first upper pad 210b”).

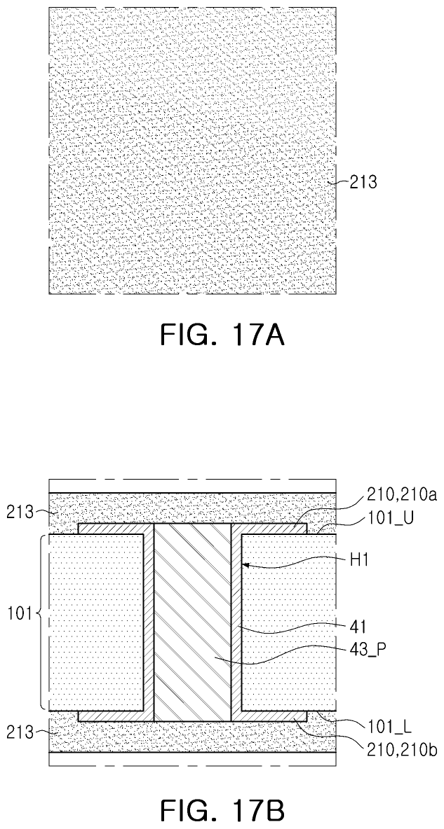

Referring to FIGS. 17A and 17B, first interlayer insulating layers 213 may be formed on the first surface 101_U and the second surface 101_L of the core substrate 101. The first interlayer insulating layers 213 may completely cover the first interconnection layer 210 and the first via insulating material 43_p on the first surface 101_U and the second surface 101_L of the core substrate 101.

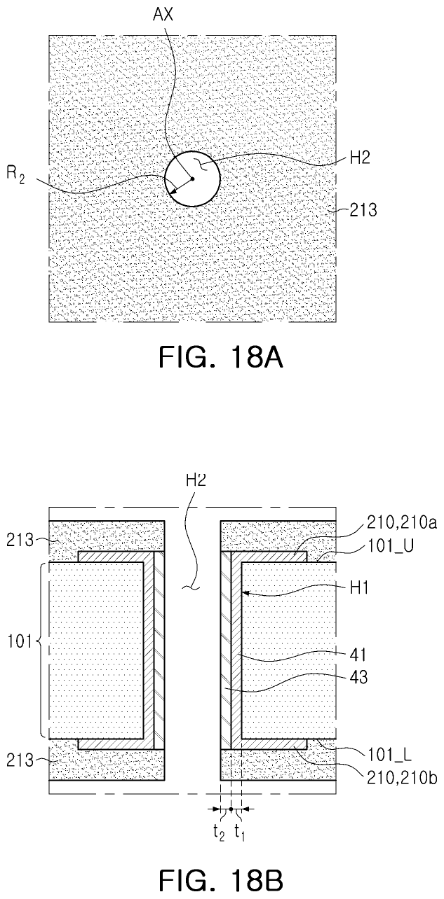

Referring to FIGS. 18A and 18B, a process of forming a second via hole H2 penetrating through the core substrate 101 and the first interlayer insulating layers 213 to penetrate through a center of the first via insulating material 43_p may be performed. The second via hole H2 may be formed to have the same central axis as the central axis AX of the first via hole H1, and may be formed to have an area smaller than the horizontal cross-sectional surface area of the first via hole H1. The second via hole H2 may be formed to have a cross-sectional surface the same as that of the first via hole H1. In an example embodiment, the first via hole H1 and the second via hole H2 may be formed to have a circular cross-sectional surface. The second via hole H2 may be formed by a mechanical drilling method or a laser processing method.

Referring to FIG. 18A, a distance of the second via hole H2 from a point on the central axis AX may be about equal to the second distance R₂.

Referring to FIG. 18B, the second via hole H2 may be formed to penetrate through a center of the first via insulating material 43_p filled in the first via hole H1. Accordingly, the first gap-fill insulating film 43 may be formed on an external wall of second via hole H2. The first gap-fill insulating film 43 may be formed to have a uniform thickness about equal to the second thickness t2 on an external wall of the second via hole H2.

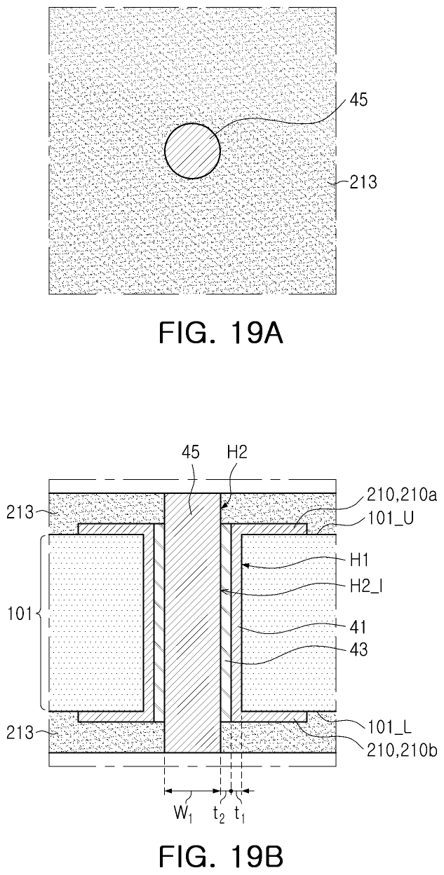

Referring to FIGS. 19A and 19B, a process of forming a second conductive film 45 filling a surface of the first interlayer insulating layers 213 and at least a portion in the second via hole H2 may be performed. The second conductive film 45 may be formed by electroless plating or electrolytic plating.

Referring to FIG. 19B, the second conductive film 45 may first be formed on an internal wall H2_I of the second via hole H2, and may completely fill the second via hole H2. In an example embodiment, in the second via hole H2, the second conductive film 45 may be referred to as a second conductive plug completely filling the second via hole H2. The second conductive plug may be formed as a cylindrical shape having a horizontal width of a first width W₁ (or “first diameter”).

Thereafter, in an embodiment, a process of patterning a portion of the second conductive film 45 formed on a surface of the first interlayer insulating layers 213 may be performed. The patterning may be performed using a photolithography technique or an etching technique. By way of the patterning, a portion of the surface of the first interlayer insulating layers 213 may be exposed, and a second interconnection layer 220 including a second lower pad 220a and a second upper pad 220b may be formed on the first interlayer insulating layers 213.

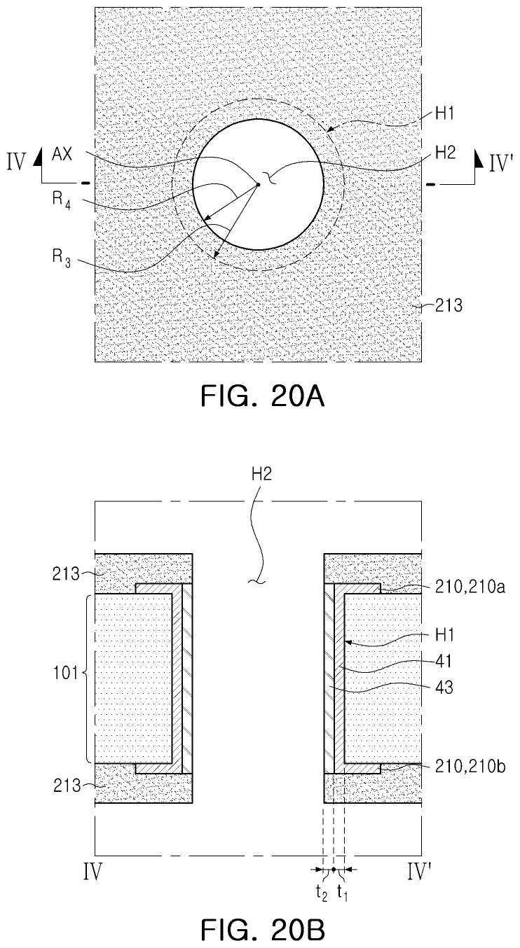

FIGS. 20A, 20B, 21A, 21B, 22A, 22B, 23A, 23B, 24A, 24B, 25A, and 25B are plan diagrams and cross-sectional diagrams illustrating a method of manufacturing a semiconductor package 3000 according to an example embodiment. FIGS. 20A to 25A are plan diagrams illustrating a method of manufacturing the semiconductor package 3000 according to example embodiments, and FIGS. 20B to 25B are cross-sectional diagrams taken along lines IV-IV′ in FIGS. 20A to 25A, respectively.

FIGS. 20A, 20B, 21A, 21B, 22A, 22B, 23A, 23B, 24A, 24B, 25A, and 25B are diagrams illustrating a method of manufacturing the semiconductor package 3000 according to example embodiments, continued from the manufacturing method described with reference to FIGS. 14A, 14B, 15A, 15B, 16A, 16B, 17A, 17B, 18A, 18B, 19A, and 19B.

Referring to FIGS. 20A and 20B, a method the same as or similar to the method described with reference to FIGS. 14 to 18 may be performed, other than the configuration in which distances from the central axis AX of the first via hole H1 and the second via hole H2 may be a third distance R₃ and a fourth distance R₄, respectively.

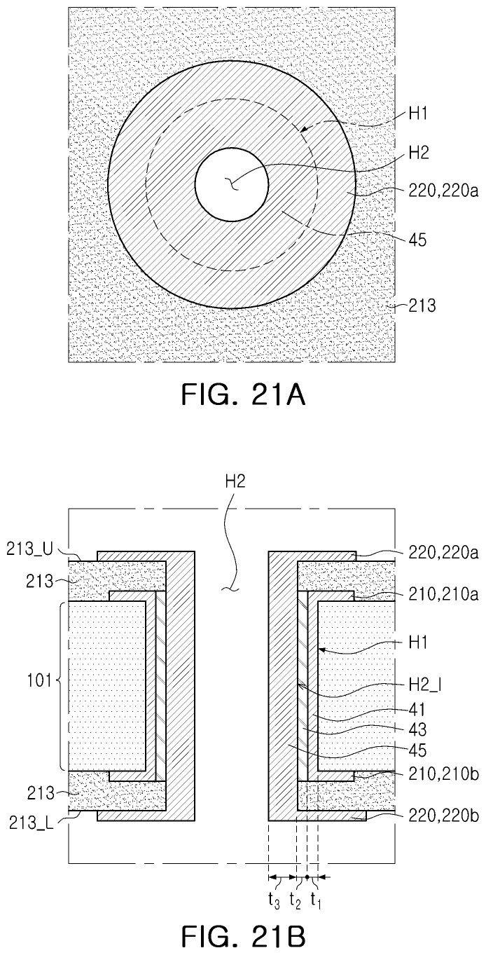

Referring to FIGS. 21A and 21B, a process of forming a second conductive film 45 on a first surface 213_U of a first interlayer insulating layer 213, a second surface 213_L opposite to the first surface, and a surface of the internal wall H2_I of the second via hole H2 may be performed. The second conductive film 45 may be formed by electroless plating or electrolytic plating.

Referring to FIG. 21B, the second conductive film 45 may be formed to have a uniform thickness about equal to a third thickness t₃ on an internal wall H2_I of the second via hole H2. In an example embodiment, in the second via hole H2, the second conductive film 45 may be referred to as a second conductive plug which is hollow therein.

Thereafter, a process of patterning a portion of the second conductive film 45 formed on the first surface 213_U and the second surface 213_L of the first interlayer insulating layer 213 may be performed. The patterning may be performed using a photolithography process or an etching process. By way of the patterning, a portion of the first surface 213_U and the second surface 213_L of the first interlayer insulating layer 213 may be exposed, and the second interconnection layer 220 including a second lower pad 220a and a second upper pad 220b may be formed on the first interlayer insulating layer 213.

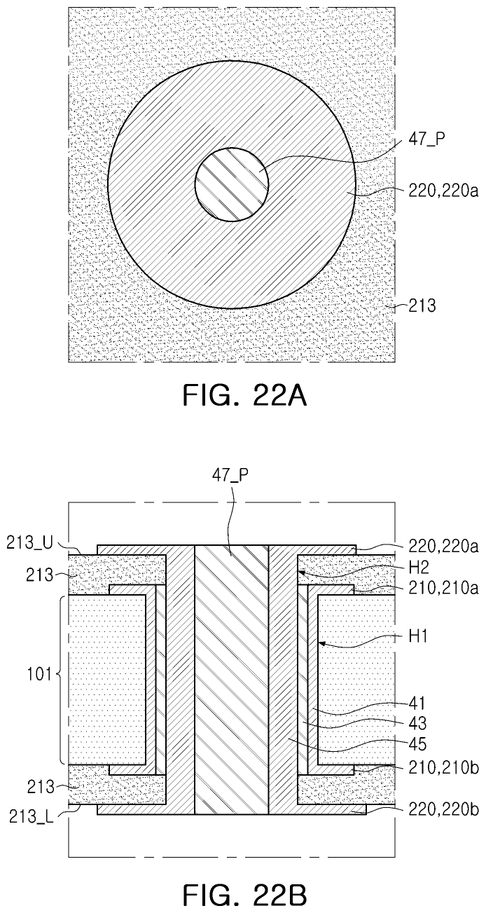

Referring to FIGS. 22A and 22B, by plugging the second via insulating material 47_p into the second via hole H2, the second via hole H2 may be completely filled with the second via insulating material 47_p. The second via insulating material 47_p may be formed using the hole plugging land (HPL) method. By way of the above method, an end of the second via insulating material 47_p may be formed to be on substantially the same level as a level of the second interconnection layer 220 (or “second lower pad 220a” to “second upper pad 220b”).

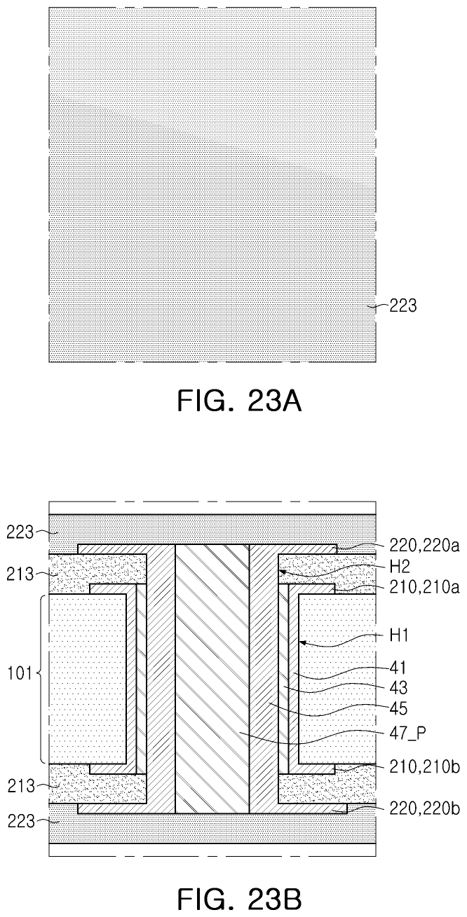

Referring to FIGS. 23A and 23B, second interlayer insulating layers 223 may be formed on the first surface 213_U and the second surface 213_L of the first interlayer insulating layer 213. The second interlayer insulating layers 223 may completely cover the second interconnection layer 220 and the second via insulating material 47_p on the first surface 213_U and the second surface 213_L of the first interlayer insulating layer 213.

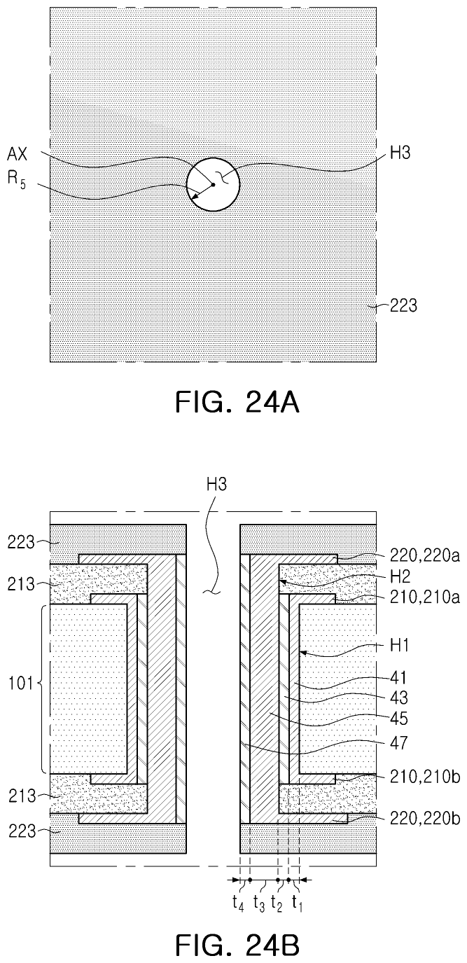

Referring to FIGS. 24A and 24B, a process of forming a third via hole H3 penetrating through the core substrate 101, the first interlayer insulating layers 213, and the second interlayer insulating layers 223 to penetrate through a center of the second via insulating material 47_p may be performed. The third via hole H3 may be formed to have the same central axis as the central axis AX of the first via hole H1 and the second via hole H2, and may have an area smaller than a horizontal cross-sectional surface area of the second via hole H2. The third via hole H3 may be formed to have a cross-sectional surface the same as those of the first via hole H1 and the second via hole H2. In an example embodiment, the third via hole H3 may be formed to have a circular cross-sectional surface. The third via hole H3 may be formed by, for example, a mechanical drilling method or a laser processing method.

Referring to FIG. 24A, a distance of the third via hole H3 from a point on the central axis AX may be a fifth distance R₅ uniformly.

Referring to FIG. 24B, the third via hole H3 may be formed to penetrate through a center of the second via insulating material 47_p filled in the second via hole H2. Accordingly, a second gap-fill insulating film 47 may be formed on an external wall of the third via hole H3. The second gap-fill insulating film 47 may be formed to have a uniform thickness about equal to the fourth thickness t₄ on an external wall of the third via hole H3.

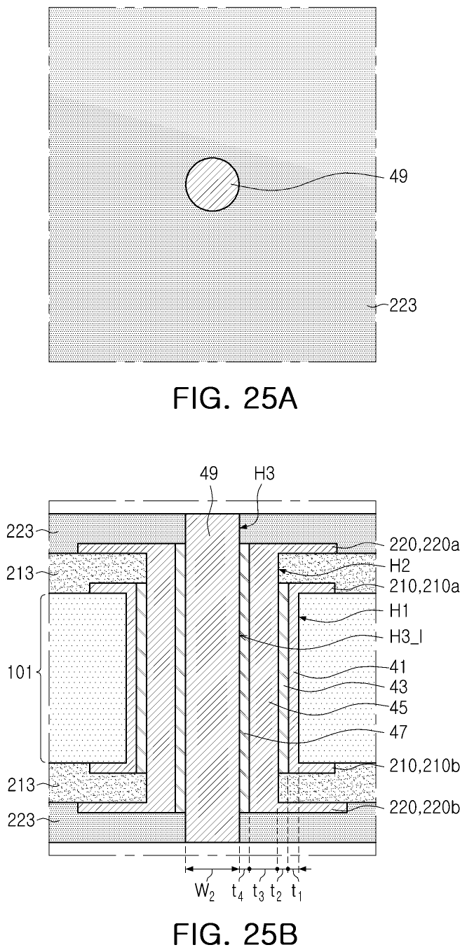

Referring to FIGS. 25A and 25B, a process of forming a third conductive film 49 filling a surface of the second interlayer insulating layers 223 and at least a portion in the third via hole H3 may be performed. The third conductive film 49 may be formed by electroless plating or electrolytic plating.

Referring to FIG. 25B, the third conductive film 49 may be formed on the internal wall H3_I of the third via hole H3, and may completely fill the third via hole H3. In an example embodiment, in the third via hole H3, the third conductive film 49 may be referred to as a third conductive plug completely filling the third via hole H3. The second conductive plug may be formed as a cylindrical shape having a horizontal width about equal to the second width W₂ (or “second diameter”).

Thereafter, in an embodiment, a process of patterning a portion of the third conductive film 49 formed on a surface of the second interlayer insulating layers 223 may be performed. The patterning may be performed using a photolithography process or an etching process. By way of the patterning, a portion of a surface of the second interlayer insulating layers 223 may be exposed, and a third interconnection layer 230 including a third lower pad 230a and a third upper pad 230b may be formed on the second interlayer insulating layers 223.

According to the aforementioned example embodiments, by including a through-via structure including a plurality of through-electrodes electrically insulated from each other, a semiconductor device having increased integration density and improved reliability may be provided.

While the present disclosure has been particularly shown and described with reference to embodiments thereof, it will be understood by those of ordinary skill in the art that various changes in form and detail may be made therein without departing from the spirit and scope of the present disclosure as defined by the following claims.

1. A semiconductor device, comprising:
a base substrate; and
a semiconductor chip disposed on the base substrate,
wherein the base substrate includes:
a core substrate;
a plurality of first interconnection substrates disposed on a first surface of the core substrate and a second surface of the core substrate opposite to the first surface;
a first through-electrode penetrating the core substrate;
a second through-electrode penetrating the core substrate and the first interconnection substrates,
wherein the second through-electrode has a same central axis as the first through-electrode, and has a width narrower than a width of the first through-electrode; and
a first insulating layer disposed between the first through-electrode and the second through-electrode and surrounding at least a portion of a side surface of the second through-electrode, and
wherein the semiconductor chip is electrically connected to at least a portion of the first and second through-electrodes.

2. The semiconductor device of claim 1,
wherein the base substrate further includes a plurality of second interconnection substrates disposed on the first interconnection substrates,
wherein the first interconnection substrates include a first interconnection layer electrically connected to the first through-electrode, and
wherein the second interconnection substrates include a second interconnection layer electrically connected to the second through-electrode.

3. The semiconductor device of claim 2,
wherein the first interconnection substrates further include a first via plug connecting the first interconnection layer to the second interconnection layer, and
wherein the second interconnection layer is electrically connected to the first through-electrode through the first via plug.

4. The semiconductor device of claim 2,
wherein at least a portion of the first insulating layer extends into the first interconnection substrates, and
wherein an upper surface of the first insulating layer is substantially on a same level as a level of an upper surface of the first interconnection layer.

5. The semiconductor device of claim 1, wherein, in a plan view, the first through-electrode has a circular cross-sectional surface which is hollow and has a first thickness, and the second through-electrode has a circular cross-sectional surface.

6. The semiconductor device of claim 5, wherein the first thickness of the circular cross-sectional surface of the first through-electrode is about 10 μm to about 100 μm.

7. The semiconductor device of claim 5, wherein the circular cross-sectional surface of the second through-electrode has a horizontal width of about 30 μm to about 100 μm.

8. The semiconductor device of claim 1, wherein, in a plan view, the first through-electrode has a quadrangular cross-sectional surface which is hollow and has a uniform thickness, and the second through-electrode has a quadrangular cross-sectional surface.

9. The semiconductor device of claim 1, wherein, in a plan view, the first through-electrode has a rounded quadrangular cross-sectional surface which is hollow and has a uniform thickness, and the second through-electrode has a rounded quadrangular cross-sectional surface.

10. The semiconductor device of claim 1,
wherein the first through-electrode has a uniform width along the core substrate, and
wherein the second through-electrode has a uniform width along the core substrate and the first interconnection substrates.

11. The semiconductor device of claim 1, wherein the base substrate further includes:
a plurality of second interconnection substrates disposed on the first interconnection substrates;
a third through-electrode penetrating the core substrate and the first and second interconnection substrates,
wherein the third through-electrode has the same central axis as the second through-electrode, and has a width narrower than the width of the second through-electrode; and
a second insulating layer disposed between the second through-electrode and the third through-electrode and surrounding at least a portion of the third through-electrode.

12. The semiconductor device of claim 11, wherein at least a portion of the second insulating layer extends into the second interconnection substrates.

13. The semiconductor device of claim 11,
wherein an external side surface of the first through-electrode is spaced apart from the central axis by a first distance, an external side surface of the second through-electrode is spaced apart from the central axis by a second distance smaller than the first distance, and an external side surface of the third through-electrode is spaced apart from the central axis by a third distance smaller than the second distance, and
wherein the first distance is about 45 μm to about 350 μm, the second distance is about 30 μm to about 200 μm, and the third distance is about 15 μm to about 50 μm.

14. A semiconductor device, comprising:
a base substrate; and
a semiconductor chip disposed on the base substrate,
wherein the base substrate includes:
a core substrate;
a plurality of first interconnection substrates disposed on a first surface of the core substrate and a second surface of the core substrate opposite to the first surface;
a first via hole penetrating the core substrate;
a second via hole penetrating the core substrate and the first interconnection substrates,
wherein the second via hole has a same central axis as the first via hole, and has a width narrower than a width of the first via hole;
a first conductive plug disposed on an internal wall of the first via hole; and
a second conductive plug disposed in at least a portion of the second via hole.

15. The semiconductor device of claim 14,
wherein the second conductive plug fills the second via hole, and
wherein the semiconductor device further includes a first insulating film disposed in the first via hole and disposed between the first conductive plug and the second conductive plug.

16. The semiconductor device of claim 15,
wherein the second conductive plug is disposed on an internal wall of the second via hole, and
wherein the semiconductor device further includes:
a plurality of second interconnection substrates disposed on the first interconnection substrates;
a third via hole penetrating the core substrate and the first and second interconnection substrates,
wherein the third via hole has the same central axis as the first and second via holes, and has a width narrower than the width of the second via hole;
a third conductive plug filling the third via hole; and
a second insulating film disposed in the second via hole and disposed between the second conductive plug and the third conductive plug.

17. The semiconductor device of claim 16, wherein, in a plan view, the first, second, and third via holes have a step difference in a direction away from the central axis.

18. A semiconductor device, comprising:
a base substrate including a core substrate, a plurality of first interconnection substrates disposed on each of a first surface of the core substrate and a second surface of the core substrate opposite to the first surface and including a plurality of first interconnection layers, a plurality of second interconnection substrates disposed on the first interconnection substrates and including a plurality of second interconnection layers, and a plurality of first through-via structures penetrating at least a portion of the core substrate, the first interconnection substrates, and the second interconnection substrates; and
a semiconductor chip disposed on the base substrate and electrically connected to at least a portion of the first and second interconnection layers,
wherein at least a portion of the plurality of first through-via structures includes:
a first through-electrode penetrating the core substrate and in contact with the first interconnection layers;
a second through-electrode penetrating the core substrate and the first interconnection substrates,
wherein the second through-electrode has a same central axis as the first through-electrode and has a width narrower than a width of the first through-electrode, and is in contact with the second interconnection layers; and
a first insulating layer disposed between the first through-electrode and the second through-electrode and substantially on a same level as the first interconnection layers.

19. The semiconductor device of claim 18,
wherein the base substrate further includes a plurality of third interconnection substrates disposed on the second interconnection substrates and including a plurality of third interconnection layers, and
wherein at least a portion of the plurality of first through-via structures further includes:
a third through-electrode penetrating the core substrate, the first interconnection substrates, and the second interconnection substrates,
wherein the third through-electrode has the same central axis as the second through-electrode, has a width narrower than the width of the second through-electrode, and is in contact with the third interconnection layers; and
a second insulating layer disposed between the second through-electrode and the third through-electrode and substantially on a same level as a level of the second interconnection layers.

20. The semiconductor device of claim 19,
wherein the base substrate further includes a fourth interconnection layer disposed on the third interconnection substrates, and a second through-via structure on a level different from a level of the first through-via structure, and
wherein the second through-via structure includes:
a first through-plug penetrating the second interconnection substrates and in contact with the second interconnection layers and the third interconnection layers;
a second through-plug penetrating the first interconnection substrates, the second interconnection substrates, and the third interconnection substrates,
wherein the second through-plug has the same central axis as the first through-plug and has a width narrower than the first through-plug, and is in contact with the first interconnection layers and the fourth interconnection layers; and
a third insulating layer disposed between the first through-plug and the second through-plug and substantially on a same level as a level of the third interconnection layers.

21-30. (canceled)
